(19) United States
(12) Patent Application Publication
(10) Pub. No.: US 2020/0219765 A1
(43) Pub. Date: Jul. 9, 2020

(54) INTERCONNECT STRUCTURES CONTAINING PATTERNABLE LOW-K DIELECTRICS AND ANTI-REFLECTIVE COATINGS AND METHOD OF FABRICATING THE SAME

(71) Applicant: International Business Machines Corporation, Armonk, NY (US)

(72) Inventors: Shyng-Tsong Chen, Armonk, NY (US); Qinghuang Lin, Armonk, NY (US)

(73) Assignee: International Business Machines Corporation, Armonk, NY (US)

(21) Appl. No.: 16/238,925

(22) Filed: Jan. 3, 2019

(51) Int. Cl. H01L 21/768; H01L 23/532

(52) U.S. Cl. CPC H01L 21/76835; H01L 21/76808; H01L 21/02282; H01L 23/53295; H01L 21/76829

(57) ABSTRACT

A process for manufacturing interconnect BEOL structures from a patternable low-k dielectric on a microcircuit substrate having an optional anti-reflective coating comprises applying to the microcircuit substrate a via coating for forming a via comprising a low-k patternable dielectric coating, exposing the via coating to a via pattern, developing the exposed via coating, curing the exposed and developed via coating to form a via film, applying a trench coating for forming a trench comprising a patternable low-k dielectric coating, exposing the trench coating to a trench pattern, developing the exposed and developed trench coating, followed by curing the trench coating to form a trench film; Curing one of the uncured coatings to form a film prevents it from inter-mixing with the other applied uncured coating. Articles of manufacture comprise products made by this process as well as dual-damascene integrated spun-on patterned low-k dielectrics, and single-damascene integrated spun-on patterned low-k dielectrics.

### FIELD OF THE INVENTION

This invention relates to microcircuit structures and methods for forming such structures and more particularly to structures having recesses such as dual damascene (“DD”) and/or single damascene recesses that include vias and/or trenches, in low dielectric constant (low-k) dielectrics.

### BACKGROUND OF THE INVENTION

The advancement of semiconductor computational speed has largely been driven by the ever smaller dimensions of semiconductor transistors and other integrated circuit (IC) components.

It is widely known that the speed of propagation of interconnect signals is one of the most important factors controlling overall circuit speed as feature sizes are reduced and the number of devices per unit area as well as the number of interconnect levels are increased. Throughout the semiconductor industry, there has been a strong drive to reduce the dielectric constant, k, of the interlayer dielectric (ILD) materials used to electrically insulate metal lines. As a result, interconnect signals travel faster through conductors due to a reduction in resistance-capacitance (RC) delays.

State-of-the-art semiconductor chips employ copper (Cu) as the electrical conductor and inorganic organosilicates as the low dielectric constant (low-k) dielectric, and have up to twelve levels of Cu/low-k interconnect layers. These Cu/low-k interconnect layers are fabricated with an interactive additive process, called dual-damascene, which includes several processing steps including, for example film deposition, patterning by lithography and reactive ion etching, liner deposition, copper (Cu) metal fill by electrochemical plating, and chemical-mechanical polishing of excessive Cu metal; these steps are described in greater detail in the following paragraphs.

When fabricating integrated circuit wiring within a multi-layered scheme, an insulating or dielectric material, e.g., silicon oxide or a low-k insulator will normally be patterned with several thousand openings to create conductive line openings (or recesses) and/or via openings using photo patterning and plasma etching techniques, e.g., photolithography with a photoresist subsequently followed by etching by plasma processes. The via openings are typically filled with an electrically conductive metal material, e.g., aluminum, copper, etc., to interconnect the active and/or passive elements of the integrated circuits. The semiconductor device is then polished to level its' surface.

A continuous cap layer is then normally deposited over the planarized surface featuring the dielectric material and conductive metal material. Next, a dielectric material is deposited over the continuous cap layer, via and conductive line openings are created within the dielectric layer as before, another conductive metal material is deposited within the openings and another continuous cap layer is deposited thereon. The process is repeated to fabricate a multi-layer interconnect wiring system. The multi-layer interconnect system built thereby is referred to in the art as a dual-damascene integration scheme.

Unfortunately, the strategy to introduce low-k materials (typically dielectrics whose dielectric constant is below that of silicon oxide) into advanced interconnects is difficult to implement due to the new materials chemistry of the low-k materials that are being introduced. Moreover, low-k materials exhibit fundamentally weaker electrical and mechanical properties as compared with silicon oxide. Further, the low-k dielectric alternatives are typically susceptible to damage during the various interconnect processing steps. The damage observed in the low-k materials is manifested by an increase in the dielectric constant and increased moisture uptake, which may result in reduced performance and degraded device reliability.

One way to overcome the integration challenges of low-k materials mentioned above is to protect low-k materials by adding at least one sacrificial hardmask layer onto a surface of the low-k material. While the hardmask layer serves to protect the low-k material, the presence of the sacrificial hardmask layer adds enormous process complexity as more film deposition, pattern transfer etch, and removal of hardmask layers are needed.

A state-of-the-art back-end-of-the-line (BEOL) integration process, called a low temperature oxide (LTO) process, employs up to eight layers of sacrificial hardmask materials to fabricate a two-layer dual-damascene interconnect structure.

For example, a via-first LTO integration for forming a dual-damascene interconnect includes the steps of: depositing a dielectric material on a substrate including a patterned conductor; forming at least one via in the dielectric material, such that at least one of the vias is positioned over the patterned conductor; depositing a layer of planarizing material on the dielectric material and in the via; depositing a layer of barrier material on the layer of planarizing material; depositing at least one layer of imaging material on the layer of barrier material; forming at least one trench in the imaging material, barrier material and planarizing material, such that the at least one trench is positioned over the via; removing the imaging material, either after or concurrently with forming the trench in the planarizing material; transferring the at least one trench to the dielectric material, such that at least one of the trenches is positioned over the via; removing the barrier material, either after or concurrently with transferring the at least one trench to the dielectric material; and removing the planarizing material.

A line-first LTO integration for forming a dual-damascene interconnect structure includes the steps of: depositing a dielectric material on a substrate including a patterned conductor; forming at least one trench in the dielectric material, such that the at least one trench is positioned over the patterned conductor; depositing a layer of planarizing material on the dielectric material and in the trench; depositing a layer of barrier material on the layer of planarizing material; depositing at least one layer of imaging material on the layer of barrier material; forming at least one via in the imaging material, barrier material and planarizing material, such that at least one of the vias is positioned over the trench and the patterned conductor; removing the imaging material, either after or concurrently with forming the via in the planarizing material; transferring the at least one via to the dielectric material, such that at least one of the vias is positioned over the trench and the patterned conductor; removing the barrier material, either after or concurrently with transferring the at least one via to the dielectric material; and removing the planarizing material.

The integration schemes, such as the LTO one mentioned above, are very complex, inefficient, and costly. For example, the via-first LTO integration scheme requires ten layers of films and twenty-one process steps to form a two-layer dual-damascene dielectric structure. In other words, 80% of films are not needed in the final interconnect structure.

Although immensely popular in semiconductor manufacturing, the prior art dual-damascene integration scheme described above suffers from several drawbacks including, for example:

(I) First, it constitutes a significant portion of manufacturing cost of advanced semiconductor chips as many layers, up to twelve layers for the state-of-the-art chips, are required to connect the minuscule transistors within a chip and to the printed circuit board.

(II) Second, it is a main yield detractor as the many layers of films required to form the interconnects generate chances for defect introduction and, thus, degrade manufacturing yields.

(III) Third, it is very inefficient and embodies enormous complexity. The current dual-damascene integration scheme requires many sacrificial films (80% of the film stack) to pattern and protect the fragile interlayer dielectric films from damage during processing. These sacrificial patterning and protective films have to be removed after patterning and copper plating.

(IV) Fourth, the performance gain by introduction of new lower-k materials is often offset by the need for higher-k non-sacrificial materials, such as a cap layer, a hardmask layer, or a thicker copper barrier layer.

(V) Fifth, the prior art complex dual-damascene process lengthens manufacturing turn-around time and R&D development cycle.

(VI) Sixth, the plasma etching process is an expensive and often unreliable process and requires significant up-front capital investment.

(VII) Seventh, the prior art patternable low-k dielectric integrations were limited to either a positive-tone or a negative-tone material. They tend to intermix with each other when either type of the patternable low-k materials is used alone in subsequent spin-on deposition processes.

In view of the above, there is a need to simplify the dual-damascene formation of interconnects, including low-k dielectrics for improved performance, reliability, cost-saving, manufacturing efficiency and the inter-mixing of same type of tone of patternable low-k dielectric in sequential processing.

### RELATED ART

The following references relate to the state of the art in the field of forming microcircuit restructures with recesses such as dual damascene recesses including vias, and recess fill or via fill compositions;

U.S. Pat. No. 8,637,395: Methods for photo-patternable low-k (PPLK) integration with curing after pattern transfer;
U.S. Application 20013/0001781: Structures And Methods For Photo-Patternable Low-K (PPLK) Integration;
U.S. Application 2001/0054766A1: Process For Making A Planar Integrated Circuit Interconnect;
U.S. Pat. No. 7,030,031: Method For Forming Damascene Structure Utilizing Planarizing Material Coupled With Diffusion Barrier Material (LTO scheme);
U.S. Pat. No. 6,649,531: Process For Forming A Damascene Structure;
U.S. Pat. No. 6,093,508: Dual Damascene Structure Formed In a Single Photoresist Film;
U.S. Application 2004/0266201A1: Method For Forming Damascene Structure Utilizing Planarizing Material Coupled With Diffusion Barrier Material;
U.S. Pat. No. 4,956,313: Via-Filling And Planarization Technique;
U.S. Application 2005/0093158—self-patterning of photo-active dielectric materials for interconnect isolation—for thermal unstable low-k polymers;
U.S. Pat. No. 7,041,748 Low Dielectric Constant Materials and Their Use In ULSI Interconnection;
U.S. Pat. No. 6,521,542, Method for Forming Dual Damascene Structure; Breyta, et al.,
U.S. Pat. No. 7,790,350, Method And Materials For Patterning a Neutral Surface:
U.S. Pat. No. 6,630,520, Composition Containing a Cross-Linkable Matrix Precursor and a Poragen, and a Porous Matrix Prepared Therefrom;
U.S. Application 20060068335, Coating Compositions for Use With an Overcoated Photoresist;
U.S. Pat. No. 7,745,540, Gap Fill Materials and Bottom Anti-Reflective Coatings Comprising Hyperbranched Polymers;
U.S. Pat. No. 6,391,472, Fill Material for Dual Damascene Processes;
U.S. Pat. No. 6,204,456, Filling Open Through Holes in a Multilayer Board;
U.S. Pat. No. 7,585,612, Coating Compositions for Use With an Overcoated Photoresist;
U.S. Application 20150097289, Hybrid Photonic and Electronic Integrated Circuits;
J. D. Adolf et al., Novel High Molecular Weight Levelers Extending Gap Fill to Smaller Features, ECS Transactions, Vol. 16, no. 22, 2009, 2009, pp. 1-10;
J. Zhou et al., Impact of Leveler Molecular Weight and Concentration on Damascene Copper Electroplating, ECS Transactions, Vol. 2, no. 6, 2007, pp. 77-92;
Takei et al., Characterization of Gap Fill Materials for Planarizing Substrate in Via-First Dual Damascene Lithography Process, Jap. J. of Appl. Phys., Vol. 46, No. 9A, 2007, pp. 5755-5761;
Q. Lin, et al, Integration of Patternable Low-k Material into Advanced Cu BEOL, Japanese Journal of Applied Physics, 49 (5), 05FB02 (2010)
Q. Lin, et al, “Multi-Level Integration of a Patternable Low-K Material in Advanced Cu BEOL,” Proc. SPIE, 7639, “Advances in Resist Materials and Processing Technology,” San Jose, Calif., March, 2010, P 76390J-1 to 9, 2010, DOI: 10.1117/12.851225
Q. Lin, et al, “Extension of Photo-Patternable Low-K Concept to 193 nm Lithography and E-beam Lithography,” Proc. SPIE, 7972, “Advances in Resist Materials and Processing Technology,” San Jose, Calif., March, 2011, 79721A-1-12, DOI: 10.1117/12.881571
U.S. Application 20050272237A1 Dual damascene integration structure and method for forming improved dual damascene integration structure;
U.S. Application 20050260845A1 Low-K dielectric etch process for dual-damascene structures;
U.S. Application 2005/0040532A1 Dual damascene integration of ultra low dielectric constant porous materials;
U.S. Application 2005/0017365A1 Replenishment of surface carbon and surface passivation of low-k porous silicon;
U.S. Pat. No. 6,939,796 System, method and apparatus for improved global dual-damascene planarization;
U.S. Pat. No. 6,939,793 Dual damascene integration scheme for preventing copper contamination of dielectric layer;
U.S. Pat. No. 6,924,226 Methods for making multiple seed layers for metallic interconnects;
U.S. Pat. No. 6,903,016 Combined conformal/non-conformal seed layers for metallic interconnects.
U.S. Pat. No. 6,88,8251 Metal spacer in single and dual damascene processing;
U.S. Pat. No. 6,846,741 Sacrificial metal spacer damascene process;
U.S. Application 2004/0077175A1 Bare shaping for improved fabrication of dual damascene integrated circuit features;
U.S. Application 2004/0072436A1 Replenishment of surface carbon and surface passivation of low-k porous silicon-based dielectric materials;
U.S. Pat. No. 6,815,333 Tri-layer masking architecture for patterning dual damascene interconnects;
U.S. Pat. No. 6,806,203 Method of forming a dual damascene structure using an amorphous silicon hard mask;
U.S. Pat. No. 6,737,345 Scheme to define laser fuse in dual damascene CU process;
U.S. Pat. No. 6,677,679 Use of SiO₂/Sin for preventing copper contamination of low-k dielectric layers;
U.S. Application 2003/0219973A1 Tri-layer masking architecture for patterning dual damascene interconnects 2003-11-27 77%
U.S. Pat. No. 6,624,053 Damascene-type interconnection structure and its production process;
U.S. Pat. No. 6,610,151 Seed layers for interconnects and methods and apparatus for their fabrication;
U.S. Pat. No. 6,586,842 Dual damascene integration scheme for preventing copper contamination of dielectric layer;
U.S. Pat. No. 6,518,668 Multiple seed layers for metallic interconnects;
U.S. Application 2002/0173079A1 Dual damascene integration scheme using a bilayer interlevel dielectric;
U.S. Pat. No. 8,659,115 Airgap Interconnect Structures with Improved Patternable Low-K Materials and Method of Fabrication;
U.S. Pat. No. 8,519,540 Self-Aligned Dual-Damascene BEOL Structures with Patternable Low-K Material and Method of Forming the Same;
U.S. Pat. No. 8,487,411 Multiple Patterning Using Improved Patternable Low-K Dielectric Materials;
U.S. Pat. No. 8,476,758 Airgap-Containing Interconnect Structure with Patternable Low-K Material and Method of Fabricating; and
U.S. Pat. No. 6,323,123 Low-K dual damascene integration process.

### SUMMARY OF THE INVENTION

The present invention provides structures, articles of manufacture and processes that address the needs for simplified interconnect fabrication, and products produced by these processes that not only provide advantages over the related art, but also to substantially obviate one or more of the foregoing and other limitations and disadvantages of the related art. Not only do the written description, claims, abstract of the disclosure, and the drawings, that follow set forth various features, objectives and advantages of the invention and how they may be realized and obtained, but these features, objectives and advantages of the invention will also become apparent by practicing the invention.

To achieve these and other advantages, and in accordance with the purpose of the invention as embodied and broadly described herein, the invention comprises a process or processes to reduce fabrication steps and costs of BEOL interconnect structures, including inter alia a process of single-damascene integration of spin-on patternable low-K materials as well as a process of dual-damascene integration of spin-on patternable low-K materials. The invention also includes products made by these processes. Additionally, the invention comprises as articles of manufacture single-damascene integrated spun-on patterned low-K materials as well as a dual-damascene integrated spun-on patterned low-K materials.

### BRIEF DESCRIPTION OF THE DRAWINGS

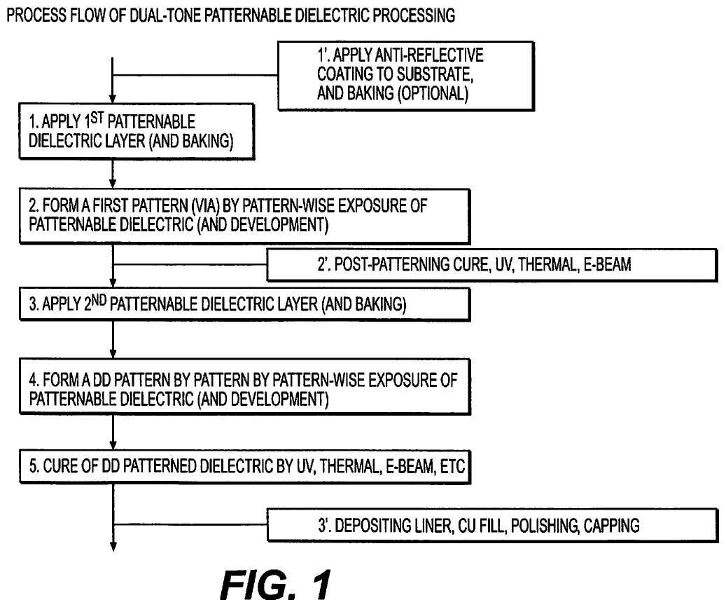

The accompanying drawings are not necessarily drawn to scale but nonetheless set out the invention, and are included to illustrate various embodiments of the invention, and together with this specification also serves to explain the principles of the invention. FIGS. 1-11 comprise illustrations of various process flow charts of the invention and various devices in cross-section made according to the process or processes of the invention.

### DETAILED DESCRIPTION OF THE DRAWINGS

In the drawings,

FIG. 1 presents a flow chart comprising process steps of the invention, i.e., “Dual-Tone Patternable Dielectric Processing” corresponding to the first embodiment of the present invention;

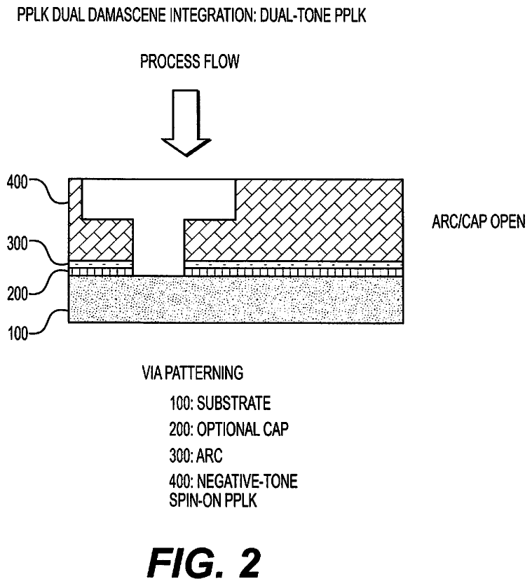

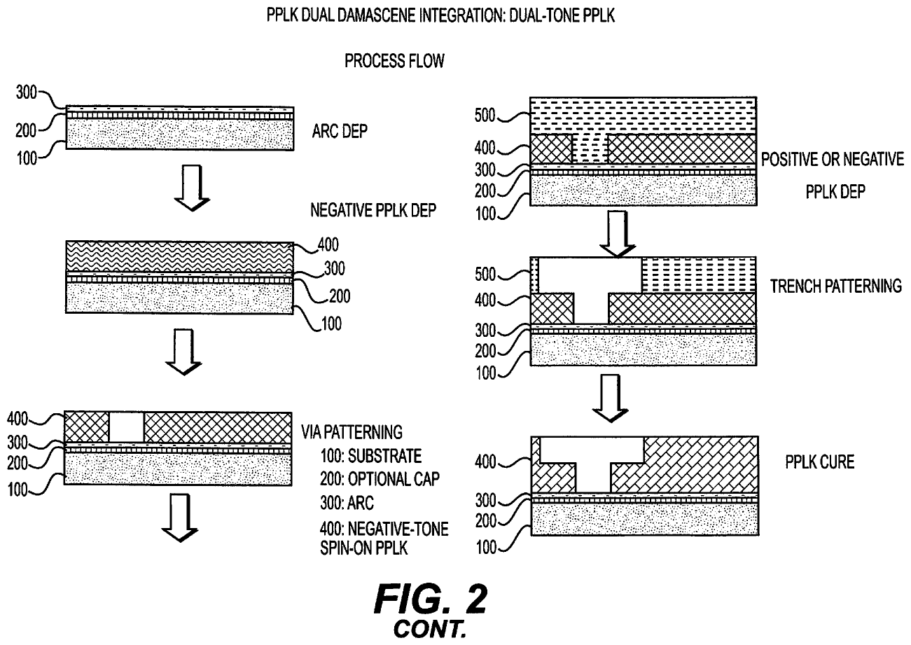

FIG. 2 and FIG. 2 cont. comprises cross-section views of steps to produce one of dual-damascene structures of the present invention, illustrating “PPLK Dual Damascene Integration: Dual-Tone PPLK Process Flow,” again corresponding to the first embodiment of the present invention;

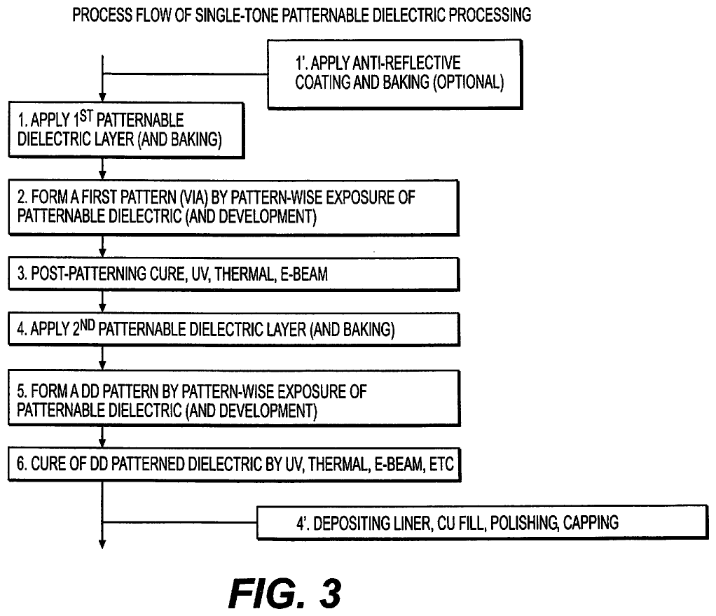

FIG. 3 presents a flow chart comprising process steps of the invention, i.e., “Process Flow of Single-Tone Patternable Dielectric Processing” corresponding to the second embodiment of the present invention;

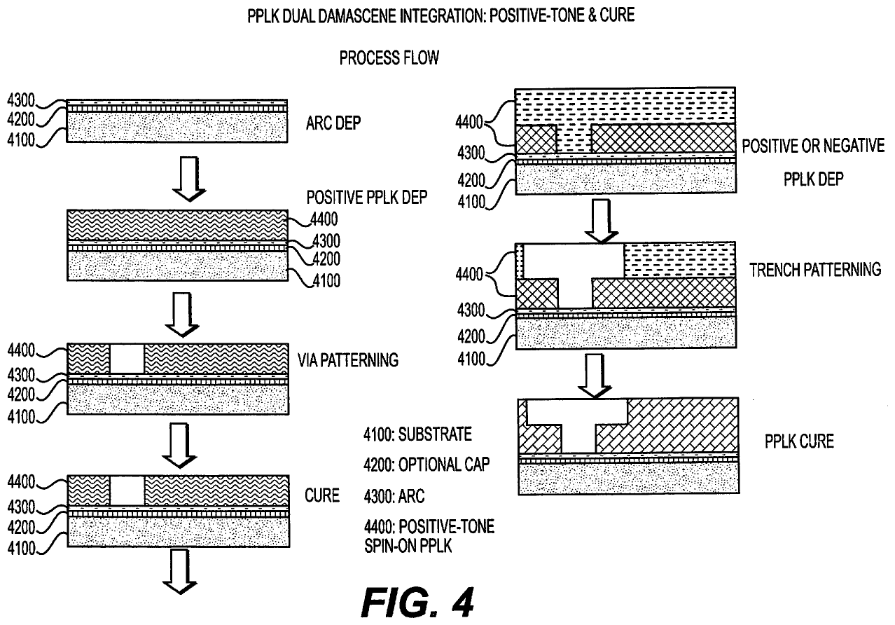

FIG. 4 comprises cross-section views of steps to produce one of dual-damascene structures of the present invention, illustrating “PPLK Dual Damascene Integration: Positive-tone & Cure Process Flow,” also corresponding to the second embodiment of the present invention;

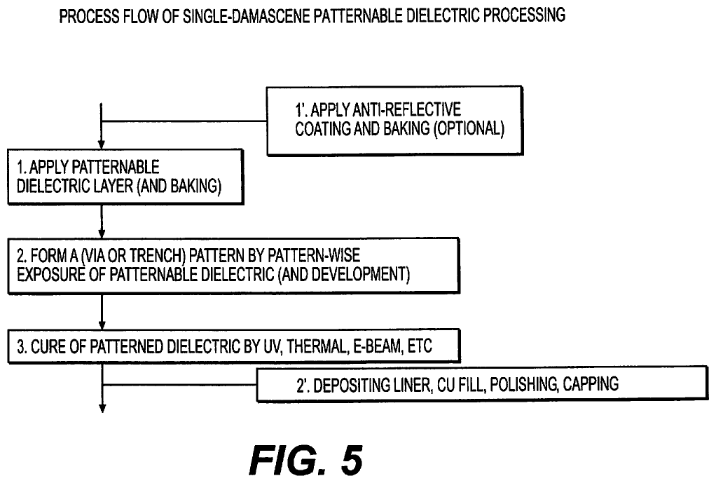

FIG. 5 presents a flow chart comprising process steps of the invention, i.e., “Process Flow of Single-Damascene Patternable Dielectric Processing” corresponding to the third embodiment of the present invention;

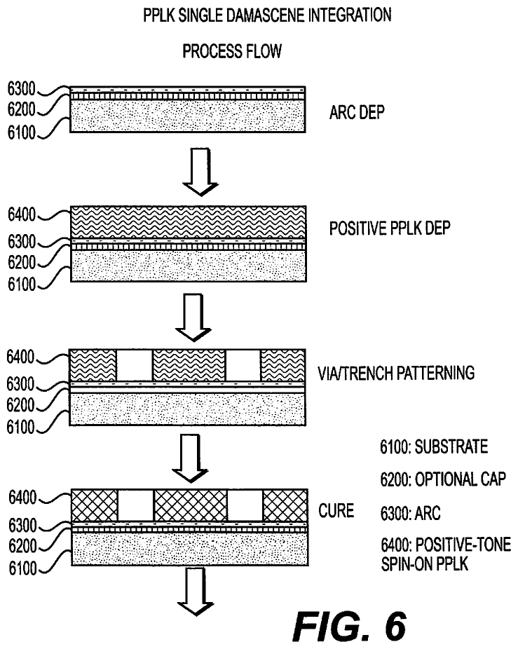

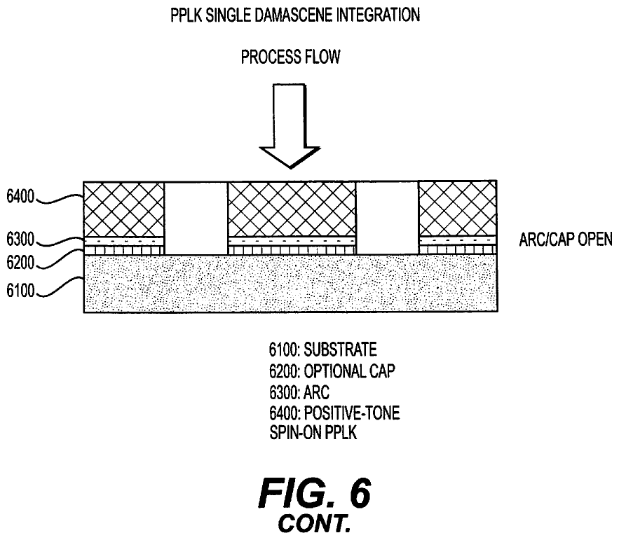

FIG. 6 and FIG. 6 cont. comprises cross-section views of steps to produce one of single-damascene structures of the present invention, illustrating “PPLK Single Damascene Integration” and corresponds to the third embodiment of the present invention;

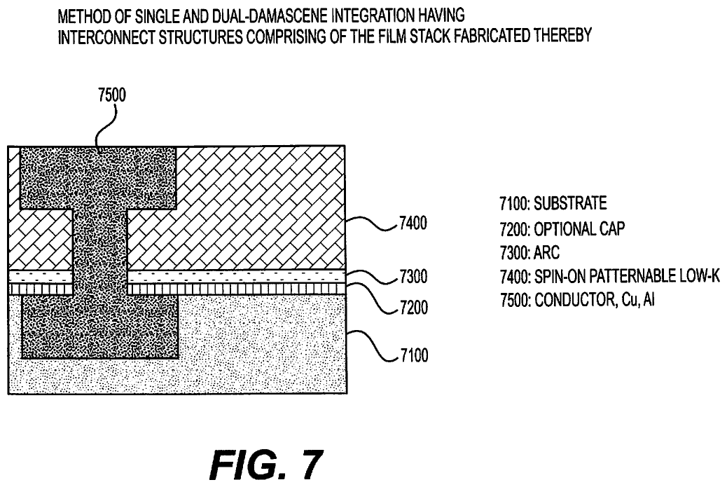

FIG. 7 comprises a cross section view of a dual damascene interconnect structure fabricated according to the invention and corresponds to the first embodiment of the present invention that teaches the use dual-tone materials to produce the articles of manufacture of the present invention as well as the second embodiment of the present invention that teaches the use of positive-tone applications of materials followed by cure to produce the articles of manufacture of the present invention,

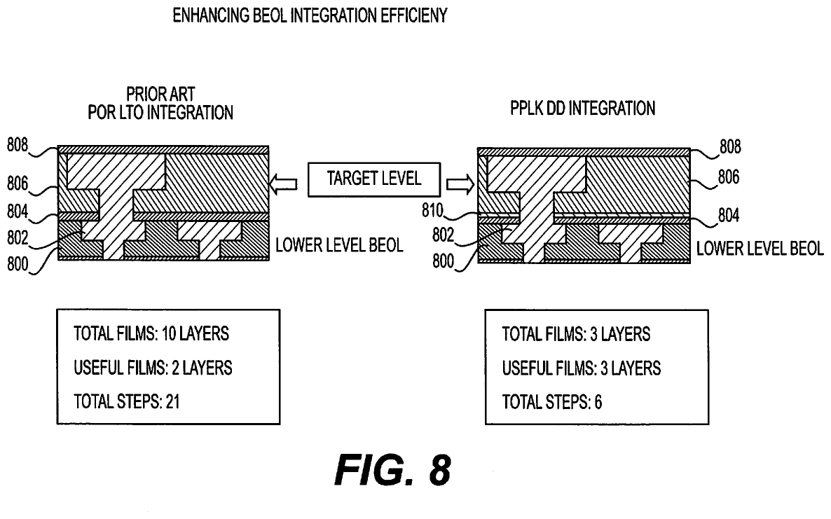

FIG. 8 illustrates “Enhancing BEOL Integration Efficiency” comprising cross section view of interconnect structures made according to the present invention (PPLK DD [Dual Damascene] Integration) compared to the prior art. (POR LTO Integration, i.e., “POR” Plan Of Record/conventional, “LTO” Low Temperature Oxide).

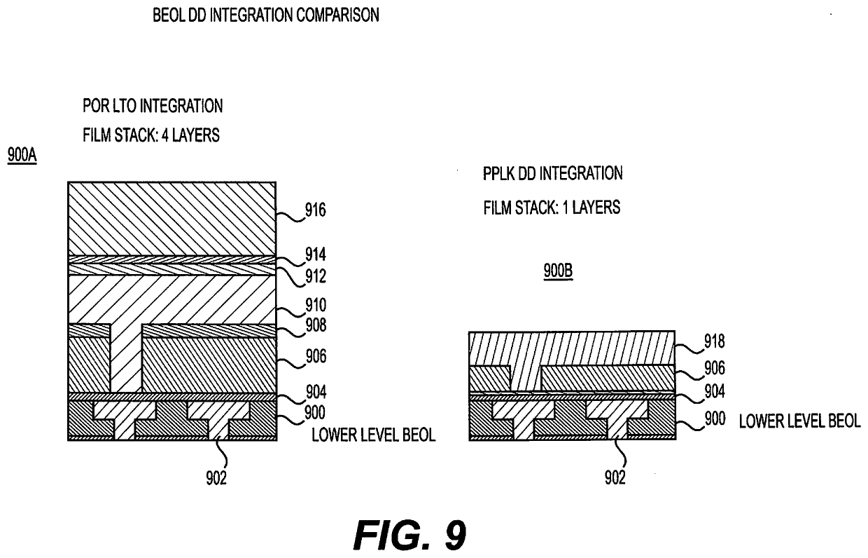

FIG. 9 illustrates “BEOL DD Integration Comparison,” comprising cross section view of interconnect structure made according to the present invention (PPLK DD [Dual Damascene] Integration) compared to the prior art. (POR LTO Integration).

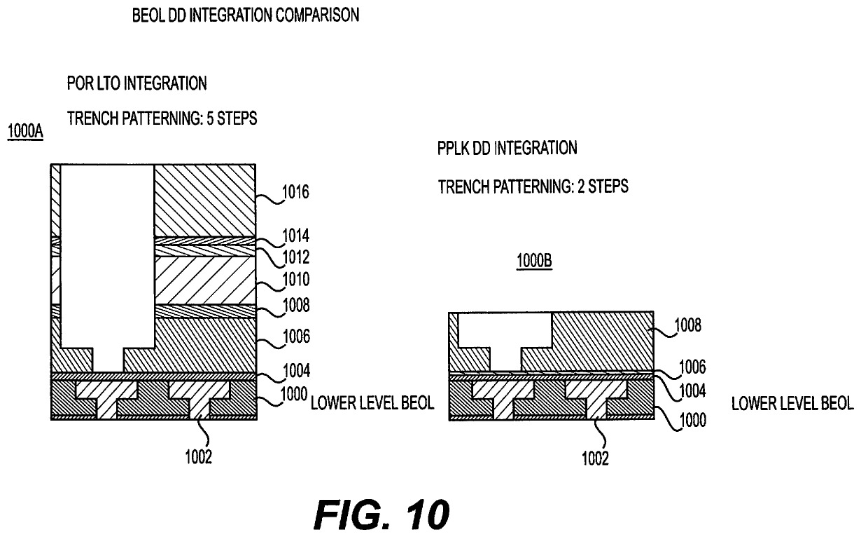

FIG. 10 also illustrates “BEOL DD Integration Comparison,” comprising side elevations in cross section of devices made according to the present invention (PPLK DD [Dual Damascene] Integration) compared to the prior art. (POR LTO Integration).

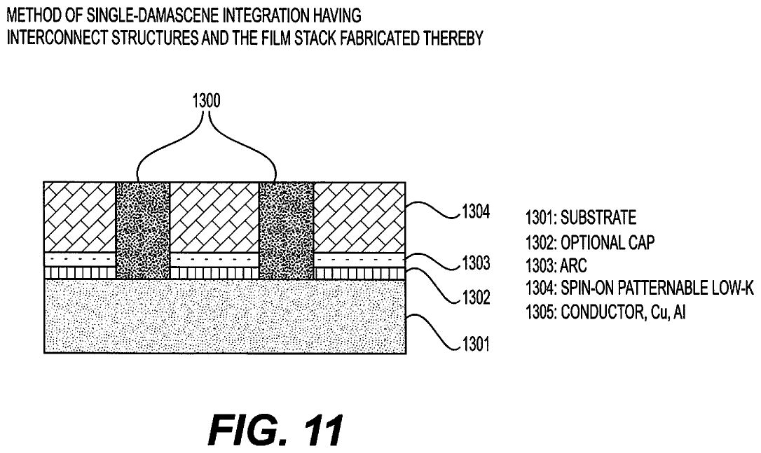

FIG. 11 illustrates cross section view of a single damascene interconnect structure fabricated according to the present invention

The Figs. refer to various materials which we identify as follows:

substrate; silicon substrate with existing pattern from previous level build;
optional cap; SiN, SiCN composition;
ARC may be using the substrate cap as ARC;
spin-on patternable low K material, composition sold as JSR PLK-5509, JSR PLK-3301 and JSR PLK-1101;
FIG. 6 “ARC/CAPOPEN,” the use of an RIE process to etch away ARC/CAP layers at the trench or via bottom of PPLK pattern;
FIG. 8, 800; Previous (lower) level dielectric layer; 802, Previous (lower) level interconnect metal wires; 804, Cap for previous level interconnect; 806, Target level dielectrics; 808, Target level cap, and 810, ARC layer;
FIG. 9, 900, previous (lower) level dielectric layer; 902, previous (lower) level interconnect metal wire; 904, previous (lower) level cap; 906, target level dielectric layer; 908, sacrificial target level dielectric level cap; 910, OPL (organic planarization layer); 912, LTO (low temperature oxide); 914, ARC, and 916, Photo resist;
FIG. 10, 1000; previous (lower) level dielectric layer; 1002, previous (lower) level dielectric layer; 1004, substrate cap; 1006, target level dielectric layer; 1008, sacrificial target level dielectric level cap; 1010, OPL (organic planarization layer); 1012, LTO (low temperature oxide); 1014, ARC; and 1016, Photo resist.

### DETAILED DESCRIPTION OF THE INVENTION

The present invention relates to a simplified method of fabricating a permanent on-chip interconnect structure from spins-on patternable low-k dielectric. More specifically, it related to a method of preventing the inter-mixing of two spin-on patternable low-k dielectric materials used in fabricating a permanent on-chip interconnect structure.

In one embodiment, the present invention relates to a simplified methods of fabricating a dual-damascene interconnect structure. Possible inter-mixing of two spin-on patternable low-k dielectric materials is reduced or avoided by employing a negative-tone patternable low-k dielectric first to form the bottom via structure first. The chemical action of cross-linking during the patterning of the negative-tone patternable low-k dielectric material reduces or prevents inter-mixing with a second spin-on patternable low-K dielectric applied over the first patternable low-k dielectric material.

The second spin-on patternable low-K dielectric can be either a negative-tone or a positive-tone material.

In another embodiment, the present invention also relates to a simplified methods of fabricating a dual-damascene interconnect structure. Either a positive-tone or a negative-tone spin-on patternable low-k dielectric material is used to form the first/bottom interconnect pattern such as via. A post-patterning cure is employed to cure the patterned first spin-on patternable low-k dielectric material. The chemical action of cross-linking during curing reduces or prevents inter-mixing with a second spin-on patternable low-K dielectric applied over the first patterned and cured patternable low-k dielectric material.

In yet another embodiment, the present invention relates to a simplified methods of fabricating a single-damascene interconnect structure. A positive-tone or a negative-tone spin-on patternable low-k dielectric material is used to form a via or a trench interconnect structure. A post-patterning cure is employed to cure the patterned spin-on patternable low-k dielectric material. The chemical action of cross-linking during curing reduces or prevents inter-mixing with any subsequent spin-on patternable low-K dielectric applied over the patterned and cured patternable low-k dielectric material.

To achieve these and other advantages, and in accordance with the purpose of this invention as embodied and broadly described herein, the following detailed embodiments comprise disclosed examples that can be embodied in various forms. The specific processes and structural details set out comprise a basis for the claims and a basis for teaching one skilled in the art to employ the present invention in any novel and useful way. The terms, phrases and Figures also set out herein provide a description of how to make and use this invention. One having ordinary skill in the relevant art, once aware of the present disclosure, could employ suitable processes and structures without undue experimentation.

In the first embodiment, we manufacture interconnect BEOL structures from a patternable low-k dielectric on a microcircuit substrate by the steps comprising; a. applying a first patternable low-k material film to said microcircuit substrate; b. forming at least one via within the said first low-k patternable dielectric film by pattern-wide exposure to an irradiation without using a separate photoresist and followed by development with a developer; c. applying a second patternable low-k material film on the said patterned first patternable low-k material film without any inter-mixing of the two patternable low-k film or degradation of the via pattern within the first patternable low-k film; d. forming at least one trench within the said second low-k patternable dielectric film by pattern-wide exposure to an irradiation without using a separate photoresist and followed by development with a developer; e. curing the said patterned first and the second patternable low-k material film to form a dual-damascene BEOL structure. In this embodiment the first and said second patternable low-k material film may comprises a positive-tone or a negative-tone photo-sensitive film, and we may apply an anti-reflective coating applied prior to the application of the first patternable low-k material film; forming at least one via or trench pattern may include a pattern-wise exposure to irradiation step, a baking step and a development step; said curing may comprises a thermal cure, an electron beam cure, a UV cure, an ion beam cure, a plasma cure, a microwave cure or any combination thereof, the separate curing step may be applied after forming the first via pattern within the first patternable patternable low-k material film, and the cured dual-damascene BEOL structure may be filled with electrical conducting materials.

In this first embodiment of interconnect BEOL structures from a patternable low-k dielectric coating on a microcircuit substrate having an optional anti-reflective coating by applying to the microcircuit substrate, a via coating for forming a via comprising a patternable low-k dielectric coating, curing (i.e., insolublizing) the via coating to form a via film, applying a trench coating for forming a trench comprising a low-k dielectric, followed by curing (i.e., insolublizing) the trench coating to form a trench film. We apply the via coating and the trench coating in any sequence.

In this process the separate coating for forming a via comprises a low-k dielectric negative-tone photo-sensitive spin-on patternable dielectric film, the separate coating for forming a trench comprises a low-k dielectric negative-tone or positive-tone photo-sensitive spin-on patternable dielectric film. By first curing (i.e., insolublizing) one of the separate coatings we prevent inter-mixing of that coating with the coating that hasn't been cured. We coat and pattern via PPLK first. We need to cure it so when we coat the trench level PPLK on top of the via level PPLK, it will not intermix with the via PPLK material already patterned with the vias. FIG. 1 in this regard comprises a flow chart of the foregoing process that we describe in the Fig. as a Process Flow of Dual-Tone Patternable Dielectric Processing.

Further in regard to the first embodiment of the present invention, a simplified method of fabricating dual-damascene interconnect structure is provided with two separate spin-son patternable low-k materials for forming a via and a trench. This includes the use of negative-tone spin-on patternable dielectrics for form the via within the bottom layer of the dual-damascene interconnect structure. The chemical action of cross-linking during the patterning of the negative-tone patternable low-k dielectric material reduces or prevents inter-mixing with a second spin-on patternable low-K dielectric applied over the first patternable low-k dielectric material. The second spin-on patternable low-K dielectric can be either a negative-tone or a positive-tone material.

The process flow is shown in FIG. 1. These steps comprise:

providing a microcircuit substrate and optionally, depositing an anti-reflective layer on the surface of the microcircuit substrate;

depositing a first negative-tone spin-on patternable low-k dielectric coating for forming a via within the first negative-tone spin-on patternable low-k dielectric coating on the microcircuit substrate with or without the additional anti-reflective layer on the substrate as the cap for the previous level substrate may be used as an ARC layer;

pattern-wise exposing the first patternable low-k dielectric coating to actinic energy to form a via pattern comprising exposed and unexposed areas;

insolublizing the via pattern within the first negative-tone spin-on patternable low-k dielectric coating with heat or actinic radiation;

selectively removing the unexposed areas by a fluid developer to form a via pattern within the first negative-tone spin-on patternable low-k dielectric coating;

depositing the separate second spin-on patternable low-k dielectric coating over the patterned first patternable low-k dielectric layer for forming a trench over the vias;

pattern-wise exposing the second coating for forming a trench with actinic energy to obtain a trench pattern comprising exposed and unexposed areas;

selectively removing the exposed or unexposed areas of the second patternable low-k dielectric coating for forming a trench by a fluid developer to form a dual damascene interconnect structure comprising a trench and a via;

curing the dual damascene structure by heat and/or actinic energy to obtain a cured dual damascene interconnect structure;

optionally filling the dual damascene interconnect structure with electrically conductive metals to obtain a dual damascene interconnect structure comprising a metal trench and a metal via embedded within the cured patterned patternable low-k dielectrics.

FIG. 2 shows cross-section view of the process flow of fabricating a dual damascene on-chip interconnect structure with spin-on patternable low-k dielectric. There is illustrated an initial structure that can be employed in one embodiment of the present invention. The initial structure of FIG. 2. includes a substrate 100, an optional dielectric cap layer 200 and an antireflective coating (ARC) 300. The ARC 300 may be located on an upper surface of the optional dielectric cap layer 200, if present. Alternatively, and when the optional dielectric cap layer 200 is not present, the ARC 300 is located on an upper surface of substrate 100.

Substrate 100 may comprise a semiconducting material, an electrically insulating material, an electrically conductive material, devices or structures made of these materials or any combination thereof (e.g., a lower level of an interconnect structure). When the substrate 100 is comprised of a semiconducting material, any semiconductor such as Si, SiGe, SiGeC, SiC, Ge alloys, GaAs, InAs, InP and other IIIN or IINI compound semiconductors, or organic semiconductors may be used. Substrate 100 may also be a flexible substrate containing devices that are suitable for high-speed roll-to-roll processing. In addition to these listed types of semiconducting materials, substrate 100 may also be a layered semiconductor such as, for example, Si/SiGe, Si/SiC, silicon-on-insulators (SOIs) or silicon germanium-on-insulators (SGOIs). These semiconductor materials may form a device, or devices or structures, which may be discrete or interconnected. These devices and device structures may be for computation, transmission, storage or display of information, such as logic devices, memory devices, switches or display devices. In some embodiments, one or more semiconductor devices such as, for example, complementary metal oxide semiconductor (CMOS) devices, strained silicon devices, carbon-based (e.g., carbon nanotubes and/or graphene) devices, phase-change memory devices, magnetic memory devices, magnetic spin switching devices, single electron transistors, quantum devices, molecule-based switches and other switching or memory devices that can be part of an integrated circuit, can be fabricated on the semiconducting material.

When the substrate 100 is an electrically insulating material, the insulating material can be an organic insulator, an inorganic insulator or a combination thereof including multilayers. The electrically insulating materials may be part of a device, or devices or structures, which may be discrete or interconnected. These devices and structures may be for logic applications or memory applications.

When the substrate 100 is an electrically conducting material, the substrate may include, for example, polySi, an elemental metal, an alloy including at least one elemental metal, a metal silicide, a metal nitride, carbon nanotubes, graphene or combinations thereof including multilayers.

When present, the optional dielectric cap layer 200 can be formed directly on an upper surface of substrate 100 utilizing a standard deposition process such as, for example, chemical vapor deposition (CVD), plasma enhanced chemical vapor deposition (PECVD), atomic layer deposition (ALD), chemical solution deposition, or evaporation. The optional dielectric cap layer 200 can include any suitable dielectric capping material such as, for example, SiC, SiN, SiO2, a carbon doped oxide, a nitrogen and hydrogen doped silicon carbide SiC(N,H) or multilayers thereof. The optional dielectric cap 200 can be a continuous layer or a discontinuous layer. The optional dielectric cap layer 200 can be a layer with graded composition in the vertical direction. The optional dielectric cap layer 200 can also be a select cap, such as CoWP, Co, Mn and the like.

After deposition of the optional dielectric cap layer 200, a post deposition treatment may be applied to the optional dielectric cap layer 200 to modify the properties of either the entire layer or the surface of the optional dielectric cap layer 200. This post deposition treatment can be selected from heat treatment, irradiation of electromagnetic wave (such of ultra-violet light), particle beam (such as an electron beam, or an ion beam), plasma treatment, chemical treatment through a gas phase or a liquid phase (such as application of a monolayer of surface modifier) or any combination thereof. This post-deposition treatment can be blanket or pattern-wise. The purpose of the post deposition treatment is to enhance the chemical, physical, electrical, and/or mechanical properties of the optional dielectric cap layer 200, such as adhesion strength. The chemical properties include the nature and/or location of surface functional groups, and hydrophilicity. The physical properties include density, moisture absorption, and heat conductivity. The mechanical properties include modulus, hardness, cohesive strength, toughness, resistance to crack and adhesion strength to its neighboring layers. The electrical properties include dielectric constant, electrical breakdown field, and leakage current.

The heat treatment should be no higher than the temperature that the underlying substrate 100 can withstand, usually 500° C. This heat treatment can be conducted in an inert environment or within a chemical environment in a gas phase or a liquid phase. This treatment step may or may not be performed in the same tool as that used in forming the optional dielectric cap layer 200.

The post deposition treatment by irradiation of electromagnetic wave can be by ultra-violet (UV) light, microwave and the like. The UV light can be broadband with a wavelength range from 100 nm to 1000 nm. The post deposition treatment can also be UV light generated by an excimer laser or other UV light source. The UV treatment dose can be a few mJ/cm2 to thousands of J/cm2. This irradiation treatment can be conducted at ambient temperature or at an elevated temperature no higher than 500° C. This irradiation treatment can be conducted in an inert environment or within a chemical environment in a gas phase or a liquid phase. The following conditions can be employed for this aspect of the present disclosure: a radiation time from 10 sec to 30 min, a temperature from room temperature to 500° C., and an environment including vacuum, or gases such as, for example, inert gas, N2, H2, O2, NH3, hydrocarbon, and SiH4. This treatment step may or may not be performed in the same tool as that used in forming the optional dielectric cap layer 200.

The post deposition treatment by plasma treatment can be selected from an oxidizing plasma, a reducing plasma or a neutral plasma. Oxidizing plasmas include, for example, O2, CO, and CO2. Reducing plasmas include, for example, H2, N2, NH3, and SiH4. The neutral plasmas include, for example, Ar and He. A plasma treatment time from 1 sec to 10 min and a plasma treatment temperature from room temperature to 400° C. can be employed. This treatment step may or may not be performed in the same tool as that used in forming the optional dielectric cap layer 200.

The post deposition chemical treatment may be conducted in a gas phase or a liquid phase. The following conditions may be employed: a treatment time from 1 sec to 30 min, a temperature from room temperature (i.e., from 20° C. to 30° C.) to 500° C. Chemicals suitable for this chemical treatment may be selected from any chemicals that improve chemical, physical, electrical, and/or mechanical properties of the dielectric cap layer, such as adhesion strength. This chemical treatment may penetrate the entire optional dielectric cap layer 200 or is limited only to the surface of the optional dielectric cap layer 200. Example chemicals include adhesion promoters such as silanes, siloxanes and silylation agents. This treatment step may or may not be performed in the same tool as that used in forming the optional dielectric cap layer 200.

The thickness of the optional dielectric cap layer 200 may vary depending on the technique used to form the same as well as the material make-up of the layer. Typically, the optional dielectric cap layer 200 has a thickness from 1 nm to 100 nm, with a thickness from 20 nm to 45 nm being more typical.

As stated above, antireflective coating (ARC) 300 can be formed on a surface of the optional dielectric cap layer 200 if present, or directly on a surface of the substrate 100 when the optional dielectric cap layer 200 is not present. In some embodiments of the present disclosure, the ARC 300 can be omitted from the initial structure 100.

The ARC 300 employed has all of the following general characteristics: (i) It acts as an ARC during a lithographic patterning process; (ii) It withstands high-temperature BEOL integration processing (up to 500° C.); (iii) It prevents poisoning of at least one of the overlying layers that serve as a photoresist by the substrate; (iv) It provides vertical wall profile and sufficient etch selectivity between one of the overlying layers and the ARC layer; (v) It serves as a permanent dielectric layer in a chip (low dielectric constant, preferably k<5, more preferably k<3.6); and (vi) It is compatible with conventional BEOL integration and produces reliable hardware. Further discussion is now provided for characteristics (i)-(v).

Characteristic (i) the ARC 300 acts as an antireflective coating (ARC) during a lithographic patterning process: ARC 300 may be designed to control reflection of light that is transmitted through an overlying photoresist material, reflected off the substrate 12 and back into the photoresist material, where it can interfere with incoming light and cause the photoresist material to be unevenly exposed. The ARC's optical constants are defined here as the index of refraction n and the extinction coefficient k. In general, ARC 300 can be modeled so as to find optimum optical parameters (n and k values) of the ARC as well as optimum thickness. The preferred optical constants of ARC 300 are in the range from n=1.2 to n=3.0 and k=0.01 to k=0.9, preferably n=1.4 to n=2.6 and k=0.02 to k=0.78 at a wavelength of 365, 248, 193 and 157, 126 nm and extreme ultraviolet (13.4 nm, 6.7 nm) radiation. The optical properties and thickness of the ARC 300 are optimized to obtain optimal resolution, profile control and to maximize the process window of the photoresist material during the subsequent patterning steps, which is well known to those ordinarily skilled in the art.

Characteristic (ii) ARC 300 can withstand high-temperature BEOL integration processing (up to 500° C.): ARC 300 must withstand the harsh processing conditions during BEOL integration. These include high temperature and intense UV cure. The process temperature can be as high as 450° C. The intensity of the light used in the UV cure process can be as high as tens of J/cm2.

Characteristic (iii) ARC 300 prevents photoresist material poisoning by the substrate: At least the photoresist material employed herein includes a chemically amplified resist. The photoresist material can be poisoned by any basic containment from the underlying substrate, such as a SiCN cap layer. The ARC 300 must serve as a barrier layer to prevent basic contaminant from the underlying substrate from diffusing into the photoresist material to poison the same.

Characteristic (iv) ARC 300 provides vertical wall profile and sufficient etch selectivity between the photoresist material and the ARC layer: ARC 300 should provide sufficient reflectivity control with reflectivity from the underlying substrate under a particular lithographic wavelength of less than 8%, preferably less than 5%, more preferably less than 2% and generate vertical side wafer profile. ARC 300 should also generate residue-free patterns with no footing. Moreover, the adhesion of the photoresist material should be sufficient to prevent pattern collapse. ARC 300 should also be designed such that the etch selectivity during a subsequent ARC/cap open process is sufficiently high so that the opening of the ARC/cap stack does not erode a significant portion of the photoresist material and degrade significantly its pattern profile. An etch selectivity (etch rate ratio of ARC/cap versus photoresist material) is greater than 1, preferably greater than 3, more preferable greater than 5.

Characteristic (v) ARC 300 serves as a permanent dielectric layer in a chip: ARC 300 remains in the final interconnect structure as a permanent dielectric layer in a chip. Therefore, ARC 300 must meet the requirements of an on-chip dielectric insulator, including electrical properties (low dielectric constant: preferably k less than 5, and more preferably k less than 3.6; dielectric breakdown field: greater than 2MV/cm, preferably greater than 4MV/cm, and more preferably greater than 6MV/cm, leakage: less than 10-5 A/cm², preferably less than 10-7 A/cm², and more preferably less than 10-9 A/cm²); mechanical properties (adhesion energy is equal to or greater than the cohesive energy of the weakest layer of the integrated film stack); and the ARC employed must pass electrical and mechanical reliability tests.

The thickness of the ARC 300 may vary depending on the technique used to form the same as well as the material make-up of the layer. Typically, the ARC 300 has a thickness from 1 nm to 200 nm, with a thickness from 10 nm to 140 nm being more typical. The ARC 300 may be inorganic or a hybrid of inorganic and organic. The ARC 300 may be a single layer or multilayer. ARC 300 may also be a graded ARC with graded composition in the vertical direction.

Inorganic antireflective coatings, such as silicon oxynitride (SiON), silicon carbide (SiC), silicon oxycarbide (SiOC), SiCOH, siloxane, silane, carbosilane, oxycarbosilane, and silsesquioxane, either as a polymer or a copolymer may be employed as ARC 300 and may be deposited, for example, by plasma-enhanced chemical vapor deposition, spin-on techniques, spray coating, dip coating, etc. ARC 300 may be a single layer or multilayer. When ARC 300 is a multilayer ARC, the deposition of each layer may be the same or a combination of deposition methods can be used. The chemical composition of ARC 300 may be uniform or graded along the vertical direction. After applying ARC 300 particularly those from a liquid phase, a post deposition baking step is usually required to remove unwanted components, such as solvent, and to effect crosslinking. The post deposition baking step of the ARC 300 is typically, but not necessarily always, performed at a temperature from 80° C. to 300° C., with a baking temperature from 120° C. to 200° C. being more typical.

In some embodiments, the as-deposited ARC may be subjected to a post deposition treatment to improve the properties of the entire layer or the surface of ARC 300. This post deposition treatment can be selected from heat treatment, irradiation of electromagnetic wave (such as ultra-violet light), particle beam (such as an electron beam, or an ion beam), plasma treatment, chemical treatment through a gas phase or a liquid phase (such as application of a monolayer of surface modifier) or any combination thereof. This post-deposition treatment can be blanket or pattern-wise. The purpose of this post deposition treatment is to enhance the chemical, physical, electrical, and/or mechanical properties of ARC 300 and/or a film stack including ARC 300 and optional dielectric cap layer 200, such as adhesion strength. The chemical properties include nature and/or location of surface functional groups, and hydrophilicity. The physical properties include density, moisture absorption, and heat conductivity. The mechanical properties include modulus, hardness, cohesive strength, toughness, resistance to crack and adhesion strength to its neighboring layers. The electrical properties include dielectric constant, electrical breakdown field, and leakage current. The conditions described above for the post treatment of the optional dielectric cap layer 200 may be used for the post treatment for the ARC.

In one embodiment, the ARC 300 that is employed is an inorganic composition that includes elements of M, C (carbon) and H (hydrogen), wherein M is selected from at least one of the elements of Si, Ge, B, Sn, Fe, Ta, Ti, Ni, Hf and La. Such an ARC is described, for example, in U.S. Patent Publication No. 2009/0079076 the entire contents of which we incorporate herein by reference. This inorganic ARC may optionally include elements of O, N, S, F or mixtures thereof. In some embodiments, M is preferably Si. In some embodiments, the ARC composition may also be referred to as a vapor deposited M:C:H: optionally X material, wherein M is as defined above, C and H are carbon and hydrogen element, respectively, and X is at least one element of O, N, S and F.

In one embodiment, ARC 300 is produced by a vapor or liquid phase deposition (such as, for example, CVD, PECVD, PVD, ALD and spin-on coating) method using appropriate precursors or combination of precursors containing elements described above.

In some embodiments, ARC 300 is a Si:C:H:X film. These Si containing films are deposited from at least one Si containing precursor. More particularly, the Si:C:H:X films are deposited from at least one Si containing precursor with, or without, additions of nitrogen and/or oxygen and/or fluorine and/or sulfur containing precursors. The Si containing precursor that is employed can comprise any Si containing compound including molecules selected from silane (SiH4) derivatives having the molecular formula SiR4, cyclic Si containing compounds including cyclocarbosilane where the R substituents may or may not be identical and are selected from H, alkyl, phenyl, vinyl, allyl, alkenyl or alkynyl groups that may be linear, branched, cyclic, polycyclic and may be functionalized with nitrogen containing substituents, any cyclic Si containing compounds including cyclosilanes, and cyclocarbosilanes.

In one embodiment, Si precursors include, but are not limited to, silane, methylsilane, dimethylsilane, trimethylsilane, tetramethylsilane, ethylsilane, diethylsilane, triethylsilane, tetraethylsilane, ethylmethylsilane, triethylmethylsilane, ethyldimethylsilane, ethyltrimethylsilane, diethyldimethylsilane, 1,1,3,3-tetrahydrido-1,3-disilacyclobutane; 1,3-disilacyclobutane; 1,3-dimethyl-1,3-dihydrido-1,3-disilylcyclobutane; 1,1,3,3, tetramethyl-1,3-disilacyclobutane; 1,1,3,3,5,5-hexahydrido-1,3,5-trisilane; 1,1,3,3,5,5-hexamethyl-1,3,5-trisilane; 1,1,1,4,4,4-hexahydrido-1,4-disilabutane; and 1,4-bis-trihydrosilyl benzene. Also the corresponding meta substituted isomers, such as dimethyl-1-propyl-3-silabutane; 2-silapropane, 1,3-disilacyclobutane, 1,3-disilapropane, 1,5-disilapentane, or 1,4-bis-trihydrosilyl benzene can be employed.

A single precursor such as silane amine, Si(Net)4, can be used as the silicon, carbon and nitrogen source. Another preferred method is a mixture of precursors, a Si containing source such as silane, disilane, or an alkylsilane such as tetramethylsilane, or trimethylsilane, and a nitrogen containing source such as ammonia, amines, nitriles, aminos, azidos, azos, and hydrizos. An additional carbon source and/or carbon and nitrogen containing source comprised of a linear, branched, cyclic or polycyclic hydrocarbon backbone of —[CH2]n-, where n is greater than or equal to 1, and may be substituted by functional groups selected from alkenes (—C═C—), alkynes (—C≡C—), amines (—C—N—), nitriles (—C≡N), amino (—NH2), azido (—N═N═N—) and azo (—N═N—) may also be required. The hydrocarbon backbone may be linear, branched, or cyclic and may include a mixture of linear branched and cyclic hydrocarbon moieties. These organic groups are well known and have standard definitions that are also well known in the art. These organic groups can be present in any organic compound.

In some embodiments, the method may further include the step of providing a parallel plate reactor, which has an area of a substrate chuck from 85 cm2 to 750 cm2, and a gap between the substrate and a top electrode from 1 cm to 12 cm. A high frequency RF power is applied to one of the electrodes at a frequency from 0.45 MHz to 200 MHz. Optionally, an additional RF power of lower frequency than the first RF power can be applied to one of the electrodes. A single source precursor or a mixture of precursors which provide a silicon, carbon and nitrogen source are introduced into a reactor.

The conditions used for the deposition step may vary depending on the desired final properties of ARC 300. Broadly, the conditions used for providing ARC 300 that contain the elements Si:C:H:X, include: setting the substrate temperature within a range from 100° C. to 700° C.; setting the high frequency RF power density within a range from 0.1 W/cm2 to 2.0 W/cm2; setting the gas flow rates within a range from 5 sccm to 10000 sccm; setting the inert carrier gases, such as helium (or/and argon) flow rate within a range from 10 sccm to 10000 sccm; setting the reactor pressure within a range from 1 Torr to 10 Torr; and setting the high frequency RF power within a range from 10 W to 1000 W. Optionally, a lower frequency power may be added to the plasma within a range from 10 W to 600 W. When the conductive area of the substrate chuck is changed by a factor of X, the RF power applied to the substrate chuck is also changed by a factor of X. Gas flows of silane, carbon and/or nitrogen gas precursors are flowed into the reactor at a flow rate within a range from 10 sccm to 1000 sccm. While gas precursors are used in the above example, liquid precursors may also be used for the deposition.

The atomic % ranges for M in such ARC materials are as follows: 0.1 atomic % to 95 atomic % in one embodiment, 0.5 atomic % to 95 atomic % in another embodiment, 1 atomic % to 60 atomic % in yet another embodiment 5 atomic % to 50 atomic % yet another embodiment. The atomic % ranges for C in the ARC are as follows: preferably 0.1 atomic % to 95 atomic %, more preferably 0.5 atomic % to 95 atomic %, most preferably 1 atomic % to 60 atomic % and most highly preferably 5 atomic % to 50 atomic %. The atomic % ranges for H in the ARC are as follows: preferably 0.1 atomic % to 50 atomic %, more preferably 0.5 atomic % to 50 atomic %, most preferably 1 atomic % to 40 atomic % and most highly preferably 5 atomic % to 30 atomic %. The atomic % ranges for X in the ARC are as follows: preferably 0 atomic % to 70 atomic %, more preferably 0.5 atomic % to 70 atomic %, most preferably 1 atomic % to 40 atomic % and most highly preferably 5 atomic % to 30 atomic %.

ARC 300 including elements of M, C and H may have a tunable index of refraction and extinction coefficient which can be optionally graded along the film thickness to match the optical properties of the substrate and the photoresist to be formed directly on it. Thus, the optical properties and the lithographic features of the ARC 300 are superior to those obtained by a conventional single layer ARC. The ARC's optical constants are defined here as the index of refraction n and the extinction coefficient k.

ARC 300 including elements of M, C and H can be deposited also in a parallel plate PECVD reactor with the substrate positioned on the grounded electrode. In some embodiments, the ARC 300 can be deposited at a substrate temperature up to 400° C., and in a high-density plasma type reactor under suitable chosen conditions. It should be noted that by changing process parameters such as bias voltage, gas mixture, gas flow, pressure and deposition temperature, the film's optical constants can be changed. In addition, the composition of the starting precursor as well as the introduction of oxygen, nitrogen, fluorine, and sulfur containing precursors also allows the tunability of these films.

In another embodiment, the ARC 300 that is employed is formed by a liquid deposition process including, for example, spin-on coating, spray coating, dip coating, brush coating, evaporation or chemical solution deposition. The ARC formed by liquid deposition comprises a polymer that has at least one monomer unit comprising the formula M-RA wherein M is at least one of the elements of Si, Ge, B, Sn, Fe, Ta, Ti, Ni, Hf and La and RA is a chromophore. Such an ARC is described in U.S. Patent Publication No. 2009/0081418 the entire contents of which we incorporated herein by reference in their entirety. In some embodiments, M within the monomer unit may also be bonded to organic ligands including elements of C and H, a cross-linking component, another chromophore or mixtures thereof. The organic ligands may further include one of the elements of O, N, S and F. When the organic ligand is bonded to M, it is bonded to M′ through C, O, N, S, or F.

In other embodiments, the ARC 300 formed by liquid deposition may also include at least one second monomer unit, in addition to the at least one monomer unit represented by the formula M-RA. When present, the at least one second monomer unit has the formula M′-RB, wherein M′ is at least one of the elements of Si, Ge, B, Sn, Fe, Ta, Ti, Ni, Hf and La, and RB is a cross-linking agent. M and M′ may be the same or different elements. In these two formulae, M and M′ within the monomer unit may be also be bonded to organic ligands including atoms of C and H, a cross-linking component, a chromophore or mixtures thereof. The organic ligands may further include one of the elements of O, N, S and F. When the organic ligand is bonded to M and M′, it is bonded to M or M′ through C, O, N, S, or F.

The liquid ARC composition comprising M-RA or M-RA and M′-RB may also comprise at least one additional component, including a separate crosslinker, an acid generator or a solvent. When liquid deposition is employed, the ARC is formed by liquid phase deposition of a liquid composition that includes an inorganic precursor that includes element of M, C and H, wherein M is at least one of the elements of Si, Ge, B, Sn, Fe, Ta, Ti, Ni, Hf and La. The inorganic precursor used in forming the ARC may optionally include elements of O, N, S, F or mixtures thereof. In some embodiments, M is preferably Si. The liquid composition also includes, in addition to the inorganic precursor, a chromophore, a cross-linking component, an acid generator and solvent.

One embodiment of an inorganic ARC composition used in the liquid deposition embodiment comprises M-RA and M′-RB units, wherein M and M′ are at least one of the elements of Si, Ge, B, Sn, Fe, Ta, Ti, Ni, Hf and La or are selected from Group IIIB to Group VIB, Group IIIA, and Group IVA. The inorganic precursor used in forming the ARC may optionally include elements of O, N, S, F or mixtures thereof. One embodiment of the ARC composition comprises the MOy unit which can be any one of many different metal-oxide forms. An exemplary list of such metal-oxide forms for a particular metal is as follows: MO3; wherein M is Sc, Y, lanthanide, and Group IIIA; B, Al, Ga or In; MO4; wherein M is Group IVB; Ti, Zr or Hf, and Group IVA; Sn or Ge; MO5; wherein M is Group VB; V, Nb or Ta; or P. The Group VB metals are also known to form stable metal oxo forms, LMO3, wherein L is an oxo; LMO; many of the listed metals form stable acetoacetato-metal complexes; LMO; many of the listed metals form stable cyclopentadienyl-metal complexes; LMO; wherein L is an alkoxy ligand; M is Sc, Y, or lanthanide, Group IVB, and Group VB; or LMO; wherein L is an alkyl or phenyl ligand; M is Group IIIA or Group IVA.

The chromophore, cross-linking component and acid generator that can be used in the liquid deposited ARC are defined in greater detail with respect to the following embodiment. In one embodiment, the ARC 300 formed by liquid deposition is characterized by the presence of a silicon-containing polymer having units selected from a siloxane, silane, carbosilane, oxycarbosilane, silsesquioxane, alkyltrialkoxysilane, tetra-alkoxysilane, or silicon-containing and pendant chromophore moieties. The polymer containing these units may be a polymer containing these units in the polymer backbone and/or in pendant groups. Preferably, the polymer contains the preferred units in its backbone. The polymer is preferably a polymer, a copolymer, a blend including at least two of any combination of polymers and/or copolymers, wherein the polymers include one monomer and the copolymers include at least two monomers and wherein the monomers of the polymers and the monomers of the copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

The polymer should be soluble to form a solution and have film-forming characteristics conducive to forming ARC 300 by conventional spin-coating. In addition to the chromophore moieties discussed below, the silicon-containing polymer also preferably contains a plurality of reactive sites distributed along the polymer for reaction with the cross-linking component.

In addition to the above, the ARC 300 in any embodiment has good etch selectivity during pattern transfer. Etch selectivities of 1.5-4 to 1 of the ARC 300 to cured dielectric materials can be obtained. Furthermore, the use of the ARC 300 as described above (vapor or liquid deposited) maintains the pattern and structural integrity after curing of the patterned dielectric materials. This is critical as the ARC 300 is retained as a permanent part of the final interconnect stack.

In some embodiments, the optional dielectric cap layer 200 and the ARC 300 can be combined into a graded cap that includes properties of both a dielectric cap layer and an ARC. Such a graded cap includes at least a lower region that includes elements of a dielectric cap and an upper region that includes elements of an ARC. The graded cap can be formed utilizing any of the methods mentioned above in forming the dielectric cap and/or ARC.

After depositing and forming the ARC layer 300, there is illustrated a structure after forming a patternable low-k dielectric layer 400 on an upper surface of the initial structure. In this particular embodiment illustrated, the patternable low-k dielectric layer 400 is formed directly on an upper surface of ARC 300. Patternable low-k dielectric layer 400 can include any conventional chemically amplified photoresist material that is well known to one skilled in the art. Patternable low-k dielectric layer 400 is a negative-tone material. These chemically amplified photoresists generate a strong acid to catalyze the crosslinking of the photoresist polymer after exposure to an irradiation source and baking.

The patternable low-k dielectric layer 400 (negative-tone) that is employed is present in a composition that includes, in addition to the photoresist material, a photoacid generator, a base additive and a solvent. When the patternable low-k dielectric layer 400 is a negative-tone photoresist material, it may be formed from a composition optionally including an additional cross-linker. By “negative-tone” it is meant that the part of the photoresist that is exposed to an actinic irradiation will not be removed by a conventional developer, while the unexposed part of the photoresist is removed. The photoacid generators, base additives and solvents are well known to those skilled in the art and, as such, details regarding those components are not fully provided.

The patternable low-k dielectric layer 400 is typically applied to an upper most surface of the initial structure 100 utilizing a conventional deposition process including, but not limited to, spin-on coating, dip coating, brushing, evaporation, blade coating, ink jet dispensing, chemical vapor deposition, and plasma enhanced chemical vapor deposition. In some embodiments, the as-deposited patternable low-k dielectric layer 400 can be subjected to a post deposition baking step to remove any unwanted components such as solvent from the applied photoresist. When such a post deposition baking step is employed, the post deposition baking step is performed at a temperature from 40° C. to 200° C., with a temperature from 60° C. to 140° C. being more typical. The duration of the post deposition baking step varies from 10 seconds to 600 seconds and is not critical herein.

The thickness of patternable low-k dielectric layer 400 may vary depending on the type of photoresist material employed as well as the type of deposition process that is used in forming the same. Typically, patternable low-k dielectric layer 400 has a thickness from 1 nm to 50000 nm, with a thickness from 10 nm to 5000 nm being more typical.

Continue on the process flow of FIG. 2, there is illustrated the structure after patterning the patternable low-k dielectric layer 400 to form relief images of a desired circuitry. An optional post-exposure baking step may be required to effect a desired photochemical reaction. When performed, the post-exposure baking step is conducted at a temperature from 60° C. to 200° C., with a post-exposure baking temperature from 80° C. to 140° C. being more typical. The duration of the post-exposure baking step varies and is not critical herein. After exposure and post-exposure baking, the latent images are developed into the relief images with an appropriate developer, usually an aqueous base solution, such as 0.26N tetramethylammoniahydroxide (TMAH) solution.

The pattern wise exposing process can be accomplished in a variety of ways, including, for example, through a mask with a lithography stepper or a scanner with an exposure light source of G-line, I-line (365 nm), DUV (248 nm, 193 nm, 157 nm, 126 nm), Extreme UV (13.4 nm, 6.7 nm), an electron beam, or an ion beam. The exposing process may be performed in a dry mode or an immersion mode. The pattern-wise exposing process also includes direct writing without the use of a mask with, for example, light, electron beam, ion beam, and scanning probe lithography.

As stated above and as illustrated in FIG. 2, the patterned patternable low-k dielectric layer 400 includes at least one via opening therein. As shown, the at least one via opening exposes an upper surface, e.g., the ARC 300, of the initial structure 100.

As stated previously, the exposure of the chemically amplified photo patternable low-k material and subsequent baking generate a strong acid from the photoacid generator of the photoresist composition. The strong acid generated from the photoacid generator on the sidewall of the photoresist patterns can catalyze crosslinking of the negative-tone photo-patternable dielectric material.

The photo patternable low-k dielectric coating material that can be employed includes a functionalized polymer, copolymer or blend including at least two of any combination of polymers and/or copolymers having one or more acid-sensitive imagable groups. After curing, the dielectric coating material is converted into a permanent on-chip dielectric material having a dielectric constant of about 7 or less. It is noted that when the dielectric coating material is comprised of a polymer, the polymer includes at least one monomer (to be described in greater detail below). When the dielectric coating material is comprised of a copolymer, the copolymer includes at least two monomers (to be described in greater detail below). The blends of polymers and/or copolymers include at least two of any combination of polymers and/or copolymers described below.

In general terms, the dielectric coating material is a composition including a polymer, a copolymer, or a blend including at least two of any combination of acid-sensitive polymers and/or copolymers, wherein the polymers include one monomer and the copolymers include at least two monomers and wherein the monomers of the polymers and the monomers of the copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

More specifically, the dielectric coating material that can be employed is a composition comprising an acid-sensitive polymer of one monomer or a copolymer of at least two monomers selected from siloxane, silane, carbosilane, oxycarbosilane, organosilicates, silsesquioxanes and the like. The dielectric coating material may also be a composition comprising a polymer of one monomer or a copolymer of at least two monomers selected from alkyltrialkoxysilane, tetra-alkoxysilane, unsaturated alkyl (such as vinyl) substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane. Additionally, the dielectric coating material may comprise a blend including at least two of any combination of acid-sensitive polymers and/or copolymers, wherein the said polymers include one monomer and the said copolymers include at least two monomers and wherein the monomers of the said polymers and the monomers of the said copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

Optionally the dielectric coating material may be a composition further comprising at least one microscopic pore generator (porogen). The pore generator may be or may not be acid sensitive.

Illustrative polymers for the dielectric coating material include, but are not limited to, siloxane, silane, carbosilane, oxycarbosilane, silsesquioxane-type polymers including caged, linear, branched or combinations thereof. In one embodiment, the dielectric coating material is a photo-patternable low k (PPLK) composition comprising a blend of these photo/acid-sensitive polymers. Examples of PPLK materials that can be employed in this application are disclosed, for example, in U.S. Pat. Nos. 7,041,748, 7,056,840, and 6,087,064, as well as U.S. Patent Application Publication No. 2008/0286467, U.S. Patent Application Publication No. 2009/0233226, U.S. Patent Application Publication No. 2009/0291389, U.S. patent application Ser. No. 12/569,200, filed Sep. 29, 2009 all of which we incorporate herein by reference in their entirety.

The additional cross-linker can be a small compound (as compared with a polymer or copolymer) or a polymer, a copolymer, or a blend including at least two of any combination of polymers and/or copolymers, wherein the polymers include one monomer and the copolymers include at least two monomers and wherein the monomers of the polymers and the monomers of the copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

The solvents that are used in the dielectric coating material composition that are compatible with the underlying photoresist patterns include organic solvents such as hydrocarbons and alcohols, and water or a mixture thereof.

The dielectric coating material can be formed utilizing a deposition process including, for example, spin-on-coating, dip coating, spray coating, brush coating, blade coating, and ink-jet dispensing. After applying the dielectric coating material a post deposition baking step is typically, but not necessarily always, required to remove unwanted components, such as solvent. When performed, the baking step can be conducted at a temperature from 40° C. to 200° C., with a baking temperature from 60° C. to 140° C. being more typical. The duration of the baking step varies from 10 seconds to 600 seconds and is not critical herein.

In one embodiment, an irradiation cure step is performed after forming the via pattern by a combination of a thermal cure and an ultra-violet (UV) cure wherein the wavelength of the ultra-violet (UV) light is from 50 nm to 300 nm and the light source for the ultra-violet (UV) cure is a UV lamp, an excimer (exciplex) laser or a combination thereof.

The excimer laser may be generated from at least one of the excimers selected from the group consisting of Ar2*, Kr2*, F2, Xe2*, ArF, KrF, XeBr, XeCl, XeCl, XeF, CaF2, KrCl, and Cl2 wherein the wavelength of the excimer laser is in the range from 50 nm to 300 nm. Additionally, the light of the ultra-violet (UV) cure may be enhanced and/or diffused with a lens or other optical diffusing device known to those skilled in the art.

In one embodiment, this post patterning cure is a combined UV/thermal cure. This combined UV/thermal cure is carried on a UV/thermal cure module under vacuum or inert atmosphere, such as N2, He and Ar. Typically, the UV/thermal cure temperature is from 100° C. to 500° C., with a cure temperature from 300° C. to 450° C. being more typical. The duration of the UV/thermal cure is from 0.5 min to 30 min with a duration from 1 min to 10 min being more typical. The UV cure module is designed to have a very low oxygen content to avoid degradation of the resultant dielectric materials. We show the metal fill, CMP and capping process for the dual damascene structure in FIG. 2,

In some embodiments, a diffusion barrier layer (liner) (not shown), which may comprise Ta, TaN, Ti, TiN, Ru, RuTaN, RuTa, W, WN or any other material that can serve as a barrier to prevent the electrically conductive material from diffusing through, is typically formed into the extended opening 23 prior to filling the same with an electrically conductive material. When present the diffusion barrier layer is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating. In some embodiments (not shown), the diffusion barrier liner may comprise a combination of layers. The thickness of the diffusion barrier liner may vary depending on the exact means of the deposition process employed as well as the material and number of layers employed. Typically, the diffusion barrier liner has a thickness from 4 to 40 nm, with a thickness from 7 to 20 nm being more typical

Following the formation of the diffusion barrier layer (liner), the remaining extended openings are filled with an electrically conductive material forming a conductive feature. The electrically conductive material used in forming the conductive feature includes, for example, polySi, an electrically conductive metal, an alloy comprising at least one electrically conductive metal, an electrically conductive metal silicide, an electrically conductive nanotube or nanowire, graphene or combinations thereof. Preferably, the electrically conductive material that is used in forming the conductive feature is a conductive metal such as Cu, W or Al, with Cu or a Cu alloy (such as AlCu) being highly preferred in the present invention. The electrically conductive material is filled into the remaining openings utilizing a conventional deposition process including, but not limited to CVD, PECVD, sputtering, chemical solution deposition or plating. A preferred filling method is electrochemical plating. The size of the electrical conductive material 26 can be the same or different on this same interconnect level.

After deposition, a conventional planarization process such as, for example, chemical mechanical polishing (CMP) can be used to provide a structure in which the diffusion barrier layer and the electrically conductive material each have an upper surface that is substantially coplanar with the upper surface of the permanent patterned dielectric structures. The resultant structure after electrically conductive material fill and planarization comprises a conductive feature of the invention. It is noted that in this embodiment, it is also possible to form different sized conductive features within the permanent patterned dielectric structures.

After forming the metal filled dual damascene structure, another dielectric cap (not shown) can be formed on the upper surfaces of each of the permanent patterned dielectric structures as well as atop an upper surface of the electrically conductive material. The “another” dielectric cap can be formed utilizing the methods described above for optional dielectric cap and the “another” dielectric cap can comprise the same or different composition as the optional dielectric cap.

In a second embodiment of the invention, we use separate coatings of dielectrics for the via and trench, i.e., a positive-tone patternable dielectric for via patterning, followed by irradiation or to heat and/or actinic energy, e.g., UV light to prevent intermixing of materials. As in the first embodiment of the invention we manufacture interconnect BEOL structures from a patternable low-k dielectric coating on a microcircuit substrate having an optional anti-reflective coating by applying to the microcircuit substrate, a via coating for forming a via comprising a patternable low-k dielectric coating, curing (i.e., insolublizing) the via coating to form a via film, applying a trench coating for forming a trench comprising a low-k dielectric, followed by curing (i.e., insolublizing) the trench coating to form a trench film. We apply the via coating and the trench coating in any sequence. In this second embodiment the separate coating for forming a via comprises a positive-tone photo-sensitive spin-on patternable low-k dielectric film, the separate coating for forming a trench comprises a negative-tone or positive-tone photo-sensitive spin-on patternable low-k dielectric film. By first curing one of the separate coatings we prevent inter-mixing of that coating with the coating that hasn't been cured. The steps of this process comprise:

providing a microcircuit substrate and optionally depositing an anti-reflective layer on the microcircuit substrate;

depositing a photo-sensitive spin-on patternable low-k dielectric coating for forming a via on the microcircuit substrate.

pattern-wise exposing the photo-sensitive spin-on patternable low-k dielectric coating for forming a via on the microcircuit substrate to actinic energy to form a via pattern comprising exposed and unexposed areas;

selectively removing the exposed or unexposed areas by a fluid developer to form a via pattern;
insolublizing the via pattern by exposing the pattered photo-sensitive spin-on patternable low-k dielectric film to heat and/or actinic energy;
depositing the separate photo patternable low-k dielectric coating for forming a trench over the vias;
pattern-wise exposing the separate photo patternable low-k dielectric coating for forming a trench to actinic energy to obtain a trench pattern;
selectively removing the exposed or unexposed areas of the separate photo patternable low-k dielectric coating for forming a trench by a fluid developer to form a dual damascene pattern comprising a trench and comprising a via;
curing the dual damascene structure by heat and/or actinic energy to obtain a cured structure;
metallizing the cured structure to obtain a structure comprising a metal trench and a metal via.
   FIG. 3 in this regard comprises a flow chart of the foregoing process.

In the second embodiment we follow the steps of the first embodiment, but wherein each of the said first and said second patternable low-k material film is a cured patternable low-k material comprising a polymer, a copolymer, a blend including at least two of any combination of polymers and/or copolymers, wherein said polymers include one monomer and said copolymers include at least two monomers and wherein said monomers of said polymers and said monomers of said copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane. In this embodiment each of the patternable low-k materials may be selected from a polymer or copolymer blend of at least two of any combination of polymers and/or copolymers selected from silsesquioxane, siloxane, silane, carbosilane, oxycarbosilane, alkyltrialkoxysilane, or tetra-alkoxysilane.

Optionally the photo-patternable low-k dielectric coating material may be a composition further comprising at least one microscopic pore generator (porogen). The pore generator may be or may not be acid sensitive.

In the third embodiment of the invention, we use positive or negative-tone patternable dielectric for via or trench patterning, followed by standard BEOL metallization CMP and cap deposition. This comprises

manufacturing interconnect BEOL structures from a patternable low-k dielectric coating on a microcircuit substrate having an optional anti-reflective coating and via coating for forming a via comprising a patternable low-k dielectric coating cured to form a via film, or a trench coating for forming a trench comprising a photo-patternable low-k dielectric coating cured to form a trench film comprising:

The process steps in this aspect of the invention comprise:

depositing a negative-tone or positive-tone photo-sensitive spin-on patternable low-k dielectric film to the microcircuit substrate;

pattern-wise exposing the spin-on patternable low-k dielectric film to actinic energy to produce exposed and unexposed areas in the coating that form via or trench patterns in the coating;

selectively removing the exposed or unexposed areas by fluid development to form a developed via or trench in the coating

converting the developed via or trench in the coating to a permanent dielectric film by curing (i.e., insolublizing) with heat and/or actinic energy;
optionally, followed by standard metallizing of the film to form a metallized via or a metallized trench. Metallization in this regard is compatible with PPLK material. FIG. 5 comprises a flow chart of the foregoing process that we describe.
each of the said first and said second patternable low-k material film is a cured patternable low-k material comprising a polymer, a copolymer, a blend including at least two of any combination of polymers and/or copolymers, wherein said polymers include one monomer and said copolymers include at least two monomers and wherein said monomers of said polymers and said monomers of said copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane. In this embodiment each of the patternable low-k materials may be selected from a polymer or copolymer blend of at least two of any combination of polymers and/or copolymers selected from silsesquioxane, siloxane, silane, carbosilane, oxycarbosilane, alkyltrialkoxysilane, or tetra-alkoxysilane.

Optionally the photo-patternable low-k dielectric coating material may be a composition further comprising at least one microscopic pore generator (porogen). The pore generator may be or may not be acid sensitive.

The third embodiment comprises a process for manufacturing interconnect BEOL structures from patternable a low-k dielectric on a microcircuit substrate comprising applying a patternable low-k material film to said microcircuit substrate; forming at least one interconnect pattern within the said low-k patternable dielectric film by pattern-wide exposure to an irradiation without using a separate photoresist followed by development with a developer; and curing the patterned patternable low-k material film to form a single-damascene BEOL structure. In this embodiment the patternable low-k material film may be a positive-tone or a negative-tone photo-sensitive film; an anti-reflective coating may be applied prior to the application of the patternable low-k material film, and the said patternable low-k material film may be a cured patternable low-k material comprising a polymer, a copolymer, a blend including at least two of any combination of polymers and/or copolymers, wherein the polymers include one monomer and the copolymers include at least two monomers.

Also in this third embodiment the monomers of these polymers and the monomers of these copolymers may comprise a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

Furthermore in this third embodiment, the patternable low-k material may comprise a polymer or copolymer blend of at least two of any combination of polymers and/or copolymers selected from silsesquioxane, siloxane, silane, carbosilane, oxycarbosilane, alkyltrialkoxysilane, or tetra-alkoxysilane; forming at least one interconnect pattern may comprise a pattern-wise exposure to irradiation step, a baking step and a development step; the curing may comprises a thermal cure, an electron beam cure, an UV cure, an ion beam cure, a plasma cure, a microwave cure or any combination thereof; and the cured single-damascene BEOL structure may be filled with an electrically conductive material.

In this third embodiment of the present invention, optionally the patternable low-k dielectric material may be a composition further comprising at least one microscopic pore generator (porogen). The pore generator may be or may not be acid sensitive.

In the third embodiment of the invention, we use positive or negative-tone patternable low-k dielectric for via or trench patterning, followed by standard BEOL metallization CMP and cap deposition. This comprises manufacturing interconnect BEOL structures from a patternable low-k dielectric coating on a microcircuit substrate having an optional anti-reflective coating and via coating for forming a via comprising a patternable low-k dielectric coating cured to form a via film, or a trench coating for forming a trench comprising a low-k dielectric coating cured to form a trench film comprising:

The process steps in this aspect of the invention comprise:

depositing a negative-tone or positive-tone photo-sensitive spin-on patternable low-k dielectric film to the microcircuit substrate;

pattern-wise exposing the spin-on patternable low-k dielectric film to heat actinic energy to produce exposed and unexposed areas in the patternable low-k dielectric coating;

selectively removing the exposed or the unexposed areas by fluid development to form a developed via or trench in the patternable low-k dielectric coating

converting the developed via or trench in the patternable low-k dielectric coating to a dielectric film by curing with heat and/or actinic energy;
optionally, followed by standard metallizing of the film to form a metallized via or a metallized trench. Metallization in this regard is compatible with the patternable low-k dielectric material.
   FIG. 5 comprises a flow chart of the foregoing process as a Process Flow of Single-Damascene Patternable Dielectric Processing.

The second embodiment and third embodiment described above employ substantially the same materials, and process conditions as the above described first embodiment. U.S. Pat. No. 8,637,395: U.S. Application 20013/0001781; U.S. Pat. Nos. 7,041,748; 8,461,039; 9,106,523; and 9,012,587 all of which we incorporated herein by reference in their entirety, also describe these materials, and process conditions employed in the second embodiment and third embodiment described above, and produce the novel and useful articles of manufacture of the invention and products produced by processes of the second embodiment and third embodiment described above invention; however, none of these references alone or in combination with one another teach or suggest the novel and useful sequence of steps of the process of employed in the second embodiment and third embodiment described above, or the product produced by the process of these embodiments.

The compounds or

compositions of matter we employ in the foregoing disclosed processes of embodiment one, embodiment two, and embodiment three, that also produces the product of this invention generally comprise the following:

### Anti-Reflective Layer

We may use the existing cap on the substrate as an ARC layer

### Negative-Tone and Positive-Tone Photo-Sensitive Spin-on Low-k Dielectric Film

We use two proprietary materials JSR PLK-3301 (for 248 nm litho) and JSR PLK-5501 (for 193 nm litho) created by IBM research jointly with JSR Corporation. They might be used as negative tone patternable low-k dielectric material.

### Metallizing The Structure

We use Cu, Co or W with liner such as TaN, TiN, Ru, and the like as metals to form the via and trench.

### Low K

“Low K” as used herein refers to k (k<3.0), ultra low k or “ULK” (k<2.5), and extreme low k (k<2.0). These values for “K,” however, can vary by plus or minus ˜10%, or plus or minus ˜20% or plus or minus ˜30%. In one embodiment, we employ “ULK” dielectric material.

### Microcircuit Material

The microcircuit material in one embodiment comprises substantially the same materials substrate 100 described in the first embodiment.

The invention also includes a product made by the foregoing process that embodies the features disclosed, as well as additional inventive features obtained by this process. The product produced by the process of this invention comprises an extremely complex structure at the interface of the cured via coating and the cured trench coating, and therefor we describe the invention as a product-by-process. In addition to the foregoing product by process, the invention comprises an article of manufacture ore se

U.S. Pat. No. 8,637,395: U.S. Application 20013/0001781; U.S. Pat. Nos. 7,041,748; 8,461,039; 9,106,523; and 9,012,587 describe various compounds and compositions of matter we use in the process of this invention, and also employed to produce the novel and useful articles of manufacture of the invention and products produced by processes of the invention. The foregoing references also teach the conditions for performing each of the process steps used in the practice of the present invention; however, none of these references alone or in combination with one another teach or suggest the novel and useful sequence of steps of the process of our present invention, or the product produced by this process that we disclose and claim to obtain our inventive objects and results. We describe these compounds, compositions of matter and conditions for performing the process steps in the detailed embodiments one through three as follows:

In embodiment one, we manufacture interconnect BEOL structures from a patternable low-k dielectric on a microcircuit substrate by the steps comprising; a. applying a first patternable low-k material film to said microcircuit substrate; b. forming at least one via within the said first low-k patternable dielectric film by pattern-wide exposure to an irradiation without using a separate photoresist and followed by development with a developer; c. applying a second patternable low-k material film on the said patterned first patternable low-k material film without any inter-mixing of the two patternable low-k film or degradation of the via pattern within the first patternable low-k film; d. forming at least one trench within the said second low-k patternable dielectric film by pattern-wide exposure to an irradiation without using a separate photoresist and followed by development with a developer; e. curing the said patterned first and the second patternable low-k material film to form a dual-damascene BEOL structure. In this embodiment the first and said second patternable low-k material film may comprises a positive-tone or a negative-tone photo-sensitive film, and we may apply an anti-reflective coating applied prior to the application of the first patternable low-k material film; forming at least one via or trench pattern may include a pattern-wise exposure to irradiation step, a baking step and a development step; said curing may comprises a thermal cure, an electron beam cure, a UV cure, an ion beam cure, a plasma cure, a microwave cure or any combination thereof, the separate curing step may be applied after forming the first via pattern within the first patternable patternable low-k material film, and the cured dual-damascene BEOL structure may be filled with electrically conductive materials.

The embodiment three comprises a process for manufacturing interconnect BEOL structures from a patternable low-k dielectric on a microcircuit substrate comprising applying a patternable low-k material film to said microcircuit substrate; forming at least one interconnect pattern within the said low-k patternable dielectric film by pattern-wide exposure to an irradiation without using a separate photoresist followed by development with a developer; and curing the patterned patternable low-k material film to form a single-damascene BEOL structure. In this embodiment the patternable low-k material film may be a positive-tone or a negative-tone photo-sensitive film; an anti-reflective coating may be applied prior to the application of the patternable low-k material film, and the said patternable low-k material film may be a cured patternable low-k material comprising a polymer, a copolymer, a blend including at least two of any combination of polymers and/or copolymers, wherein the polymers include one monomer and the copolymers include at least two monomers.

Also in this embodiment three the monomers of these polymers and the monomers of these copolymers may comprise a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane

Furthermore in this embodiment three, the patternable low-k material may comprise a polymer or copolymer blend of at least two of any combination of polymers and/or copolymers selected from silsesquioxane, siloxane, silane, carbosilane, oxycarbosilane, alkyltrialkoxysilane, or tetra-alkoxysilane; forming at least one interconnect pattern may comprise a pattern-wise exposure to irradiation step, a baking step and a development step; the curing may comprises a thermal cure, an electron beam cure, an UV cure, an ion beam cure, a plasma cure, a microwave cure or any combination thereof; and the cured single-damascene BEOL structure may be filled with an electrically conductive material.

In this embodiment three of the present invention, optionally the patternable low-k dielectric material may be a composition further comprising at least one microscopic pore generator (porogen). The pore generator may be or may not be acid sensitive.

In the foregoing embodiments where we apply two films, i.e., the via coating and the trench coating, we apply them in any sequence. Curing one of the uncured coatings to form a film prevents it from substantially inter-mixing with the other applied uncured coating.

We practice the invention of the present application by preparing structures following the process steps of FIG. 1, or FIG. 3 or FIG. 5.

To summarize, the invention comprises a process for manufacturing interconnect BEOL structures from a patternable low-k dielectric on a microcircuit substrate having an optional anti-reflective coating by applying to the microcircuit substrate a via coating for forming a via comprising a patternable low-k dielectric coating, exposing the via coating to a via pattern, developing the exposed or unexposed areas via coating to form a via pattern, curing the exposed and developed via coating to form a cured via pattern, applying a trench coating for forming a trench comprising a patternable low-k dielectric coating, exposing the trench coating to a trench pattern, developing the exposed or the unexposed areas and developed trench coating to form a trench pattern, followed by curing the trench coating to form a cured trench film; the via coating and the trench coating being applied in any sequence. Curing one of the uncured coatings to form a film prevents it from inter-mixing with the other applied uncured coating. Articles of manufacture comprise products made by this process as well as dual-damascene integrated spun-on patterned low-k dielectrics, and single-damascene integrated spun-on patterned low-k dielectrics.

Throughout this specification, abstract of the disclosure, claims, and in the drawings the inventors intend to include various equivalents, including without limitation, equivalent elements, materials, compounds, compositions, conditions, processes, structures, and even though set out individually, also include combinations of these equivalents such as the two component, three component, or four component combinations, or more as well as combinations of such equivalent elements, materials, compounds, compositions conditions, processes, structures in any ratios or in any manner.

Any numerical ranges describing the invention as set forth throughout the specification also include any combination of the lower ends of the ranges with the higher ends of the ranges, and any single numerical value, or any single numerical value that will reduce the scope of the lower limits of the range or the scope of the higher limits of the range, and also includes ranges falling within any of these ranges.

The terms “about,” “substantial,” or “substantially” as applied to any claim or any parameters herein, such as a numerical value, including values used to describe numerical ranges, means slight variations in the parameter. In another embodiment, the terms “about,” “substantial,” or “substantially,” when employed to define numerical parameter include, e.g., a variation up to five per-cent, ten per-cent, 15 per-cent, or 20 per-cent, or somewhat higher or lower than the upper limit of five per-cent, ten per-cent, 15 per-cent, or 20 per-cent. The term “up to” that defines numerical parameters means a lower limit comprising zero or a miniscule number, e.g., 0.001.

The terms “about,” “substantial” and “substantially” also mean that which is largely or for the most part or entirely specified. The inventors also employ the terms “substantial,” “substantially,” and “about” in the same way as a person with ordinary skill in the art would understand them or employ them. The phrase “at least” means one or a combination of the elements, materials, compounds, or conditions, and the like specified herein, where “combination” is defined above. The terms “written description,” “specification,” “claims,” “drawings,” and “abstract” as used herein refer to the written description, specification, claims, drawings, and abstract of the disclosure as originally filed, and if not specifically stated herein, the written description, specification, claims, drawings, and abstract of the disclosure as subsequently amended.

All scientific journal articles and other articles, including internet sites, as well as issued and pending patents that this written description mentions including the references cited in such scientific journal articles and other articles, including internet sites, and such patents, are incorporated herein by reference in their entirety and for the purpose cited in this written description and for all other disclosures contained in such scientific journal articles and other articles, including internet sites as well as patents and the aforesaid references cited therein, as all or any one may bear on or apply in whole or in part, not only to the foregoing written description, but also the following claims, abstract of the disclosure, and appended drawings.

Any statement or statements made in this specification in the singular also includes or include the plural and vice-versa. The use of any personal pronoun(s) in this specification refers to the inventor(s) named in this specification.

Although the inventors have described their invention by reference to some embodiments, other embodiments defined by the doctrine of equivalents are intended to be included as falling within the broad scope and spirit of the foregoing written description, and the following claims, abstract of the disclosure, and appended drawing.

1. A process for manufacturing interconnect BEOL dual damascene structures comprising:
applying a via patternable low-k material film and a trench patternable low-k material film to a microcircuit substrate in any sequence, directly one over the other;
forming at least one via within said via patternable low-k material film by pattern-wide exposure to an irradiation without using a separate photoresist followed by development with a developer to obtain a patterned via low-k material film, and curing said patterned via low-k material film to obtain a via pattern within said via patternable low-k material film, wherein said irradiation causes a cross-linking within the patterned via low-k material film; and
forming at least one trench within said trench patternable low-k dielectric film by pattern-wide exposure to an irradiation without using a separate photoresist followed by development with a developer to obtain a patterned trench low-k material film, and curing said patterned trench low-k material film to obtain a trench pattern within said trench patternable low-k material film,
said via patternable low-k material film and said trench patternable low-k material film being applied one over the other and cured separately to substantially prevent any intermixing between them in the process of applying them to said microcircuit substrate,
wherein cross-linking within said patterned via low-k material film substantial prevents inter-mixing of said patternable low-k material films.

2. The process of claim 1 wherein said via patternable low-k material film is a negative-tone photo-sensitive film and said trench patternable low-k material film is a positive-tone or a negative-tone photo-sensitive film.

3. The process of claim 1 wherein an anti-reflective coating is applied prior to the application of the first applied film in the sequence of applying said patternable low-k material films.

4. The process of claim 1 wherein each of said via patternable low-k material film and said trench patternable low-k material film is a cured patternable low-k material comprising a polymer, a copolymer, a blend including at least two of any combination of polymers and/or copolymers, wherein said polymers include one monomer and said copolymers include at least two monomers and wherein said monomers of said polymers and said monomers of said copolymers are selected from a siloxane, silane, carbosilane, oxycarbosilane, silsesquioxane, alkyltrialkoxysilane, tetra-alkoxysilane, unsaturated alkyl substituted silsesquioxane, unsaturated alkyl substituted siloxane, unsaturated alkyl substituted silane, an unsaturated alkyl substituted carbosilane, unsaturated alkyl substituted oxycarbosilane, carbosilane substituted silsesquioxane, carbosilane substituted siloxane, carbosilane substituted silane, carbosilane substituted carbosilane, carbosilane substituted oxycarbosilane, oxycarbosilane substituted silsesquioxane, oxycarbosilane substituted siloxane, oxycarbosilane substituted silane, oxycarbosilane substituted carbosilane, and oxycarbosilane substituted oxycarbosilane.

5. The process of claim 3 wherein each of said patternable low-k materials is selected from a polymer or copolymer blend of at least two of any combination of polymers and/or copolymers selected from silsesquioxane, siloxane, silane, carbosilane, oxycarbosilane, alkyltrialkoxysilane, or tetra-alkoxysilane.

6. The process of claim 1 wherein said forming at least one via pattern or trench pattern includes a pattern-wise exposure to an irradiation step, a baking step and a development step.

7. The process of claim 1 wherein said curing of each of said patterned via low-k material film and said patterned trench low-k material film comprises a thermal cure, an electron beam cure, a UV cure, an ion beam cure, a plasma cure, a microwave cure or any combination thereof.

8. The process of claim 1 wherein a separate curing step is applied after forming the via pattern within the first applied film in the sequence of applying said patternable low-k material films.

9. The process of claim 1 wherein the cured BEOL structure is filled with one or more electrical conducting material.

10-17. (canceled)

18. A product produced by the process for manufacturing interconnect BEOL structures on a microcircuit substrate having an optional anti-reflective coating comprising:
applying a via patternable low-k material film and a trench patternable low-k material film to said microcircuit substrate in any sequence, one over the other;
forming at least one via within said via patternable low-k material film by pattern-wide exposure to an irradiation without using a separate photoresist followed by development with a developer to obtain a patterned via low-k material film, and curing said patterned via low-k material film to obtain a via pattern within said via patternable low-k material film, wherein said irradiation causes a cross-linking within said patterned via low-k material film; and
forming at least one trench within said trench patternable low-k dielectric film by pattern-wide exposure to an irradiation without using a separate photoresist followed by development with a developer to obtain a patterned trench low-k material film, and curing said patterned trench low-k material film to obtain a trench pattern within said trench patternable low-k material film,
said via patternable low-k material film and said trench patternable low-k material film being applied one over the other and cured separately to substantially prevent any intermixing between them in the process of applying them to said microcircuit substrate,
wherein cross-linking within said patterned via low-k material film substantial prevents inter-mixing of said patternable low-k material films.

19. The product produced by the process of claim 18 wherein said coating for forming a via comprises a negative-tone photo-sensitive spin-on patternable low-k dielectric film, said coating for forming a trench comprises a negative-tone or a positive-tone photo-sensitive spin-on patternable low-k dielectric film.

20. The product produced by the process of claim 18 wherein said coating for forming a via comprises a positive-tone photo-sensitive spin-on patternable low-k dielectric film, said coating for forming a trench comprises a negative-tone or positive-tone photo-sensitive spin-on patternable low-k dielectric film, metallizing said via and said trench to obtain a structure comprising a metal trench and a metal via.
